(19) United States
(12) Patent Application Publication
(10) Pub. No.: US 2024/0145267 A1
(43) Pub. Date: May 2, 2024

(54) SUBSTRATE PROCESSING APPARATUS AND SUBSTRATE PROCESSING METHOD

(71) Applicant: Tokyo Electron Limited, Tokyo (JP)

(72) Inventor: Einosuke TSUDA, Yamanashi (JP)

(21) Appl. No.: 18/381,075

(22) Filed: Oct. 17, 2023

(30) Foreign Application Priority Data
Oct. 31, 2022 (JP) 2022-174045

(51) Int. Cl. H01L 21/67; F21V 7/00; H01L 21/687

(52) U.S. Cl. CPC H01L 21/67115; F21V 7/0008; H01L 21/68742; F21Y 2115/10

(57) ABSTRACT

A substrate processing apparatus removes carbon-containing substances present at a peripheral edge of a substrate, which includes: a processing container; a substrate stage that places the substrate thereon within the processing container and supports at least a portion of the substrate excluding the peripheral edge; an LED heating unit that has a plurality of LED elements and irradiates the peripheral edge of the substrate with LED light from the plurality of LED elements, thereby heating the carbon-containing substances present at the peripheral edge; and a gas supply unit that supplies an oxygen-containing gas to the peripheral edge of the substrate.

### CROSS-REFERENCE TO RELATED APPLICATIONS

The present application is based on and claims priority from Japanese Patent Application No. 2022-174045, filed on Oct. 31, 2022, with the Japan Patent Office, the disclosure of which is incorporated herein in its entirety by reference.

### TECHNICAL FIELD

The present disclosure relates to a substrate processing apparatus and a substrate processing method.

### BACKGROUND

As for the processing of substrates such as semiconductor wafers, there are processes in which carbon-containing substances such as an organic resin are formed on the substrate, and processes in which carbon-containing substances remain on the substrate. If such carbon-containing substances are present at the peripheral edge of the substrate, there is a possibility that a problem such as carbon contamination or a chuck defect in the next process will occur. Thus, techniques have been suggested for removing the carbon-containing substances on the peripheral edge of the substrate.

For example, Japanese Patent Laid-Open Publication No. 2007-184393 proposes a technique in which a laser light is focused, in a spot form, on a fluorocarbon film adhering to the outer periphery of the back surface of a substrate so that the fluorocarbon film is heated and then the fluorocarbon film is reactively removed through supplying of ozone. Japanese National Publication of International Patent Application No. 2010-531538 proposes a technique of cleaning, for example, a polymer formed on the bevel edge of a substrate through irradiation of plasma. Further, U.S. Pat. No. 11,031,262 proposes a technique of cleaning the bevel edge of a substrate by using remote plasma.

### SUMMARY

According to an aspect of the present disclosure, a substrate processing apparatus removes carbon-containing substances present at a peripheral edge of a substrate. The substrate processing apparatus includes: a processing container; a substrate stage that places the substrate thereon within the processing container and supports at least a portion of the substrate excluding the peripheral edge; an LED heating unit that has a plurality of LED elements and irradiates the peripheral edge of the substrate with LED light from the plurality of LED elements, thereby heating the carbon-containing substances present at the peripheral edge; and a gas supply unit that supplies an oxygen-containing gas to the peripheral edge of the substrate.

According to the present disclosure, provided is a substrate processing apparatus and a substrate processing method, in which it is possible to efficiently remove carbon-containing substances present at the peripheral edge of the substrate, with good controllability while suppressing damage to the substrate.

### BRIEF DESCRIPTION OF THE DRAWINGS

FIG. 1 is a cross-sectional view schematically illustrating an example of a substrate processing apparatus according to one embodiment.

FIG. 2 is a view illustrating the relationship between LED wavelength and emissivity when C, Si, and Al are irradiated with LEDs.

FIG. 3 is a partial cross-sectional view illustrating a portion corresponding to a peripheral edge of a substrate in the substrate processing apparatus of FIG. 1, in an enlarged scale.

FIGS. 4A to 4C are views illustrating a process of removing carbon-containing substances present at the peripheral edge of the substrate, by the substrate processing apparatus of FIG. 1.

FIG. 5 is a cross-sectional view schematically illustrating an example of a substrate processing apparatus according to another embodiment.

FIG. 6 is a cross-sectional view schematically illustrating an example of a substrate processing apparatus according to still another embodiment.

### DETAILED DESCRIPTION

In the following detailed description, reference is made to the accompanying drawings, which form a part thereof. The illustrative embodiments described in the detailed description, drawings, and claims are not meant to be limiting. Other embodiments may be utilized, and other changes may be made without departing from the spirit or scope of the subject matter presented here.

Hereinafter, embodiments will be described with reference to accompanying drawings.

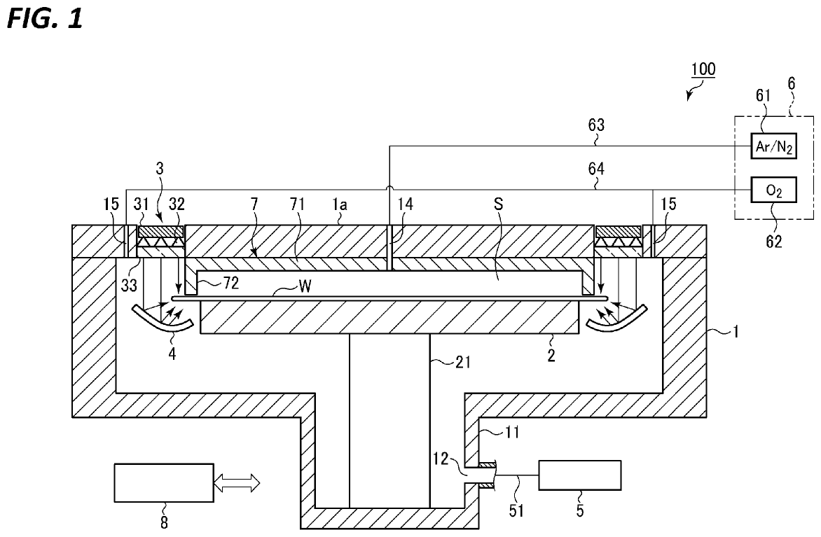

FIG. 1 is a cross-sectional view schematically illustrating an example of a substrate processing apparatus according to one embodiment.

A substrate processing apparatus 100 is configured as an apparatus of removing carbon-containing substances present at the peripheral edge of a substrate such as a semiconductor wafer, e.g., a bevel (bevel edge). As for the carbon-containing substances, carbon or carbon compounds such as organic resins may be exemplified.

The substrate processing apparatus 100 includes a processing container 1, a substrate stage 2, an LED heating unit 3, a mirror 4, an exhaust device 5, a gas supply unit 6, a shielding member 7, and a control unit 8.

The processing container 1 is made of a metal such as aluminum. Inside the processing container 1, a processing space where a substrate W is processed is formed. Further, the processing container 1 has a protrusion 11 in which an exhaust space is formed, at the center of the bottom thereof. The substrate stage 2, the mirror 4, and the shielding member 7 are provided inside the processing container 1.

The substrate stage 2, on which the substrate W is placed, is made of, for example, a metal such as aluminum. The substrate stage 2 has a disc shape with a diameter smaller than the substrate W, and is configured to support at least a portion of the substrate W, excluding the peripheral edge to be processed. The substrate stage 2 is supported by a support member 21 extending upwards from the bottom of the protrusion 11 of the processing container 1.

An elevating pin (not illustrated) for transferring the substrate W is provided in the substrate stage 2 such that the elevating pin can protrude and retract from the upper surface of the substrate stage 2. The substrate stage 2 may be cooled by a cooling mechanism. An electrostatic chuck for electrostatically adsorbing the substrate W may be provided on the top surface of the substrate stage 2.

The LED heating unit 3 is configured to irradiate the peripheral edge (bevel) of the substrate W with LED light from a plurality of LED elements and to heat carbon-containing substances present at the peripheral edge of the substrate W. The LED heating unit 3 has a ring-like overall shape with a diameter larger than the substrate stage 2, and is provided at a position above the substrate W on the substrate stage 2, for example, on a ceiling wall 1a of the processing container 1. The LED heating unit 3 includes a ring-shaped base member 31, a plurality of LED elements 32 provided on the entire lower surface of the base member 31, and a ring-shaped light transmitting member 33 having the same size as the base member 31. The light transmitting member 33 is provided below the LED elements 32 so as to be fitted into the ceiling wall 1a. The light transmitting member 33 is fitted into the ceiling wall 1a via a sealing member (not illustrated), and the LED elements 32 are disposed in the air atmosphere. Power is supplied to the LED elements 32 from a power source (not illustrated), and thereby, LED light is emitted from the LED elements 32. Then, the emitted LED light passes through the light transmitting member 33 and is irradiated on the peripheral edge (bevel) of the substrate W, thereby heating the carbon-containing substances present at the peripheral edge of the substrate W. The heating temperature at this time may be 300° C. or less, and is preferably 200 to 300° C.

The plurality of LED elements 32 may be arranged in various layouts on the base member 31, and may be divided into zones. In the case of zone division, heating uniformity may be increased by controlling the output for each zone.

Light emitting diodes (LEDs) heat objects by using electromagnetic radiation caused by recombination of electrons and holes, and have a merit in a fast temperature rise rate. Further, it is possible to selectively heat the carbon-containing substances by adjusting the wavelength of light emitted from the LEDs. Therefore, in the present embodiment, while the peripheral edge (bevel) of the substrate W is irradiated with LED light from the plurality of LED elements 32 of the LED heating unit 3 and is heated, as described below, an oxygen-containing gas is supplied and causes a reaction so as to remove the carbon-containing substances on the peripheral edge (bevel) of the substrate W.

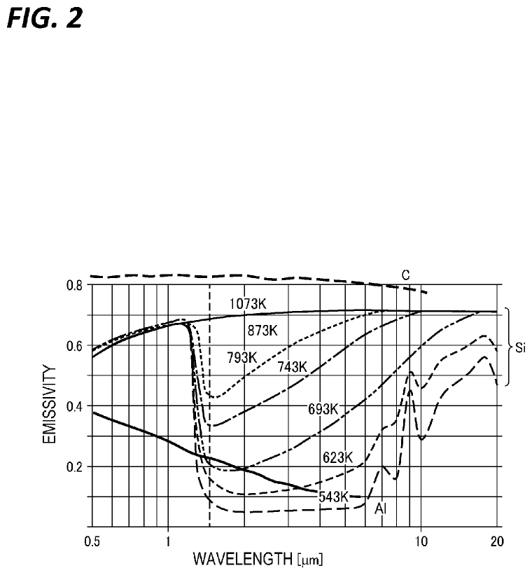

FIG. 2 is a view illustrating the relationship between LED wavelength and emissivity when C, Si, and Al are irradiated with LEDs. Meanwhile, in the wavelength range of 1.5 to 3 μm, the emissivity of Si and Al decreases whereas such a decrease is not observed in C. Therefore, from the viewpoint of selectively heating carbon compounds on the peripheral edge (bevel) of the substrate W, it is desirable that the wavelength of light emitted from the LED elements 32 is 1.5 to 3 μm.

The mirror 4 is configured as a reflective member that reflects the light emitted from the LED elements 32 of the LED heating unit 3. The mirror 4 reflects the LED light emitted from the LED elements 32, and guides the reflected light to the back surface portion of the peripheral edge (bevel) of the substrate W. The position of the mirror 4 is adjusted so that a desired position is irradiated with the reflected light.

The inner diameter of the LED heating unit 3 may be smaller than the outer diameter of the substrate W on the substrate stage 2, and the outer diameter may be larger than the outer diameter of the substrate W on the substrate stage. Accordingly, the LED light from the inner LED elements 32 of the LED heating unit 3 is directly irradiated on the front surface (top surface) portion of the peripheral edge (bevel) of the substrate W, and the reflected light, which has been emitted from the outer LED elements 32 and reflected by the mirror 4, is irradiated on the back surface (bottom surface) portion of the peripheral edge (bevel) of the substrate W.

The exhaust device 5 exhausts gases inside the processing container 1, and is connected to an exhaust port 12 provided in the side wall of the protrusion 11 in the processing container 1, via an exhaust pipe 51. The exhaust device 5 has a vacuum pump and an automatic pressure control valve. While the vacuum pump is operated to exhaust gases, the pressure inside the processing container 1 is controlled to a predetermined vacuum pressure by the automatic pressure control valve.

The gas supply unit 6 supplies an inert gas and an oxygen-containing gas. This example includes an Ar/N₂ gas source 61 that supplies Ar gas and/or N₂ gas as the inert gases, and an O₂ gas source 62 that supplies O₂ gas as the oxygen-containing gas. One end of a first gas pipe 63 is connected to the Ar/N₂ gas source 61, and the other end of the first gas pipe 63 is connected to a first gas flow path 14 located at the center of the ceiling wall 1a of the processing container 1. Then, Ar gas and/or N₂ gas are supplied from the Ar/N₂ gas source 61 into the processing container 1 via the first gas pipe 63 and the first gas flow path 14. One end of a second gas pipe 64 is connected to the O₂ gas source 62, and the second gas pipe 64 is branched and connected to second gas flow paths 15 provided in the peripheral edge of the ceiling wall 1a of the processing container 1. Then, O₂ gas is supplied from the O₂ gas source 62 to the peripheral edge of the substrate W within the processing container 1, via the second gas pipe 64 and the second gas flow paths 15. As for the inert gas, other rare gases such as He gas may be used in addition to Ar gas and N₂ gas. As for the oxygen-containing gas, in addition to O₂ gas, O₃ gas may be used.

The oxygen-containing gas such as O₂ gas is a gas for reacting with and vaporizing the carbon-containing substances present at the peripheral edge (bevel) of the substrate W heated by irradiation of the LED elements 32. The inert gas such as Ar gas or N₂ gas is a gas for preventing the oxygen-containing gas from invading the central portion of the substrate W.

The shielding member 7 obstructs the flow of the oxygen-containing gas to the central portion of the substrate W on the substrate stage 2, and is attached to the bottom surface of the ceiling wall 1a of the processing container 1. The shielding member 7 is provided to face the substrate W on the substrate stage 2. The outer circumferential surface of the shielding member 7 is located inside the inner circumferential surface of the LED heating unit 3, and the outer periphery extends from the ceiling wall 1a to a position close to the top surface of the substrate W.

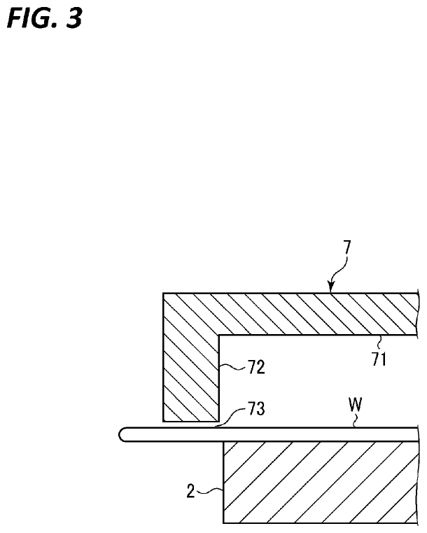

The shielding member 7 has a disc-shaped base 71 attached to the ceiling wall 1a, and an outer wall 72 extending downwards from the peripheral edge of the base 71, and has a cylindrical shape inside which a space S is formed. The outer periphery of the base 71 and the outer wall 72 constitute the above-mentioned outer periphery. The first flow path 14 is formed so as to pass through the ceiling wall 1a and the base 71 and to face the space S, and Ar gas and/or N₂ gas, which are inert gases, are supplied from the first flow path 14 to the space S. As illustrated in FIG. 3, a gap 73 is formed between the lower end of the outer wall 72 (outer periphery) and the substrate W, and the inert gas supplied to the space S flows from the gap 73 to the outside of the shielding member 7 so as to prevent the oxygen-containing gas from flowing into the space S. From the viewpoint of effectively preventing the oxygen-containing gas from flowing into the space S, the size of the gap 73 may be about 1 mm or less, and preferably 0.2 to 1 mm. The outer diameter of the shielding member 7 may be larger than the outer diameter of the substrate stage 2. This makes it easy to remove the carbon-containing substances on the back surface portion of the peripheral edge (bevel) of the substrate W.

The outer circumferential surface of the shielding member 7 may be mirror-finished. Thus, the shielding member 7 may be suppressed from being heated by irradiation of LED light, and the heating efficiency of the peripheral edge (bevel) of the substrate W may be improved. From the same viewpoint, the inner surface of the processing container 1 may be mirror-finished.

The controller 8 is constituted by a computer including, for example, a CPU and a storage, and controls components of the substrate processing apparatus 100, such as, for example, the exhaust device 5, the gas supply unit 6, and the power source of the LED elements 32. The control unit 8 causes each component of the substrate processing apparatus 100 to perform a predetermined operation on the basis of the processing recipe stored in a storage medium of the storage.

A loading/unloading port (not illustrated) through which the substrate W is loaded and unloaded is provided in the side wall of the processing container 1, and the loading/unloading port may be opened/closed by a gate valve. The substrate stage 2 may be raised and lowered by an elevating mechanism (not illustrated). When the substrate W is transported, the substrate stage 2 is lowered to a transport position lower than that in FIG. 1, and during processing, the substrate stage 2 is raised to a processing position of FIG. 1.

Next, in the substrate processing apparatus 100 configured in this manner, the substrate processing operation will be described.

First, the substrate W is loaded into the processing container 1 through the loading/unloading port (not illustrated). The substrate W is placed on the substrate stage 2 at the transport position, and then, the substrate stage 2 is raised to the processing position illustrated in FIG. 1.

Then, while Ar gas and/or N₂ gas are supplied as inert gases from the Ar/N₂ gas source 61 of the gas supply unit 6 to the space S within the processing container 1, the exhaust device 5 exhausts gases so that the pressure within the processing container 1 reaches a predetermined vacuum pressure.

In a state where Ar gas and/or N₂ gas, which are inert gases, are supplied to the space S within the processing container 1, while O₂ gas is supplied as an oxygen-containing gas from the O₂ gas source 62 of the gas supply unit to the peripheral edge of the substrate W, LED light is emitted from the LED elements 32 of the LED heating unit 3. The LED light is irradiated on the peripheral edge (bevel) of the substrate W, and carbon-containing substances present at the peripheral edge (bevel) of the substrate W are heated. Then, a reaction between the carbon-containing substances and O₂ occurs, so that the carbon-containing substances are removed. Here, the heating temperature may be 300° C. or less, preferably 200 to 300° C., and the output of the LED elements 32 is adjusted so that heating is performed at a desired temperature.

Here, the peripheral edge of the substrate W and the central portion are separated by the shielding member 7, and then, Ar gas and/or N₂ gas, which are inert gases supplied to the space S, flow out to the outer periphery of the processing container 1 through the gap 73. Thus, O₂ gas which is an oxygen-containing gas is prevented from flowing into the space S. For this reason, at the central portion of the substrate W, almost no removal reaction for the carbon-containing substances occurs, whereas only at the peripheral edge of the substrate W, the carbon-containing substances are substantially selectively removed. Here, by providing a cooling mechanism in the substrate stage 2, it is possible to more effectively suppress the removal reaction for the carbon-containing substances at the central portion of the substrate W.

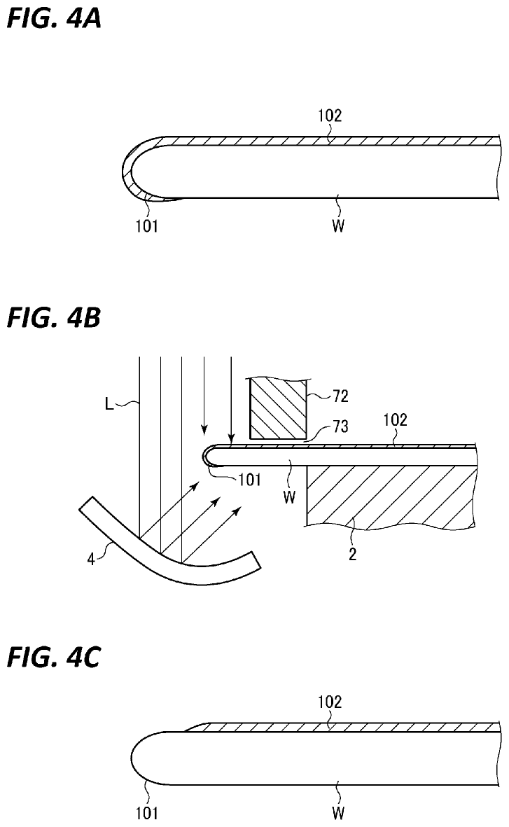

At this time, the removal of the carbon-containing substances at the peripheral edge of the substrate W will be more specifically described. FIGS. 4A to 4C are views illustrating a process of removing carbon-containing substances present at the peripheral edge of the substrate W, by the substrate processing apparatus 100.

For example, as illustrated in FIG. 4A, when a carbon-containing film 102 for forming an air gap in a device, such as a polyurea film, is formed as carbon-containing substances on the substrate W, the carbon-containing film 102 is also formed on a bevel 101 which is the peripheral edge of the substrate W.

However, if the carbon-containing film 102 is formed on the bevel 101 which is the peripheral edge of the substrate W, there is a possibility that a problem such as carbon contamination or a chuck defect in the next process will occur. For this reason, in the present embodiment, as illustrated in FIG. 4B, the bevel 101 of the substrate W, which is the peripheral edge of the substrate W, is irradiated with LED light from the LED elements 32 of the LED heating unit 3.

In this way, by irradiating the bevel 101 with LED light L from the LED heating unit 3, it is possible to heat the carbon-containing substances 102 on the bevel 101 of the substrate W.

Here, the LED heating unit 3 may be configured such that its inner diameter is smaller than the outer diameter of the substrate W on the substrate stage 2, and its outer diameter is larger than the outer diameter of the substrate W on the substrate stage. Accordingly, from the inner LED elements 32 of the LED heating unit 3, LED light may be directly irradiated on the front surface (top surface) portion of the bevel 101 of the substrate W, and LED light, which has been emitted from the outer LED elements 32 and reflected by the mirror 4, may be irradiated on the back surface portion of the bevel 101 of the substrate W. Therefore, it is possible to efficiently heat the carbon-containing film 102 on the bevel 101.

Then, in this manner, by heating the carbon-containing film 102 on the bevel 101 of the substrate W, and supplying O₂ gas as an oxygen-containing gas to the peripheral edge of the substrate W, the carbon-containing film 102 and O₂ gas react, so that the carbon-containing film 102 is removed.

Here, the shielding member 7 obstructs the flow of the oxygen-containing gas toward the central portion of the substrate W on the substrate stage 2, and Ar gas and/or N₂ gas as inert gases are supplied to the space S and flow to the outside of the shielding member 7 through the gap 73. This prevents O₂ gas which is an oxygen-containing gas from flowing into the space S, so that at the central portion of the substrate W, no reaction between the carbon-containing film 102 which is the carbon-containing substances and the O₂ gas substantially occurs. For this reason, it is possible to selectively remove only the carbon-containing film 102 on the bevel 101 which is the peripheral edge of the substrate W. Here, by setting the size of the gap 73 to about 1 mm or less, preferably 0.2 to 1 mm, it is possible to effectively prevent the oxygen-containing gas from flowing into the space S. By making the outer diameter of the shielding member 7 larger than the outer diameter of the substrate stage 2, the oxygen-containing gas is more easily supplied to the back surface portion of the bevel 101 of the substrate W than to the front surface portion. Accordingly, the carbon-containing substances (the carbon-containing film 102) on the back surface portion of the bevel 101, which cause a chuck defect, may be reliably removed.

In the above technique described in Japanese Patent Laid-Open Publication No. 2007-184393, a laser light is focused, in a spot form, on a fluorocarbon film adhering to the outer periphery of the back surface of a substrate so that the fluorocarbon film is removed through heating and supply of ozone. This technique is essentially different from that of the present embodiment in which carbon-containing substances in a wide range at the peripheral edge of the substrate are removed. The LED elements 32 used for the LED heating unit 3 of the present embodiment are characterized in that the light broadly spreads, and are efficient because the light may heat a wider area than the laser light in the case described in Japanese Patent Laid-Open Publication No. 2007-184393. Since the LED elements 32 themselves are small elements, the layout is flexible and the zone division is also easy. Thus, the LED elements 32 may be provided only in a necessary range. This is advantageous in terms of cost.

In the above techniques described in Japanese National Publication of International Patent Application No. 2010-531538 and U.S. Pat. No. 11,031,262, for example, a polymer formed on the bevel edge of the substrate is etched and removed through irradiation of plasma, and only the bevel edge is irradiated with plasma. For this reason, it is difficult to control the device, and it is difficult to obtain high plasma uniformity. Then, there is also a problem in that plasma damages the substrate. Further, it is difficult to adjust a balance between plasma ignition conditions and the expected etching performance. On the other hand, in the present embodiment, due to irradiation of light by the LED heating unit, a necessary location may be subjected to irradiation with good controllability. Thus, unlike in the case where plasma is used, there is no problem in, for example, the controllability, and also there is no plasma damage to the substrate. Further, there is no need to consider plasma ignition conditions. Furthermore, LED elements may be divided into zones and the light intensity may be controlled depending on the zones, resulting in high uniformity of processing. Further, since the LED elements may be turned ON/OFF instantaneously, the processing time may be shortened.

In this way, according to the present embodiment, it is possible to efficiently remove carbon-containing substances present at the peripheral edge of the substrate, with good controllability, while suppressing damage to the substrate. Further, by using the LED elements, the above-mentioned other effects, which are not obtained in the laser light processing or the plasma processing, are also obtained.

Next, another embodiment will be described.

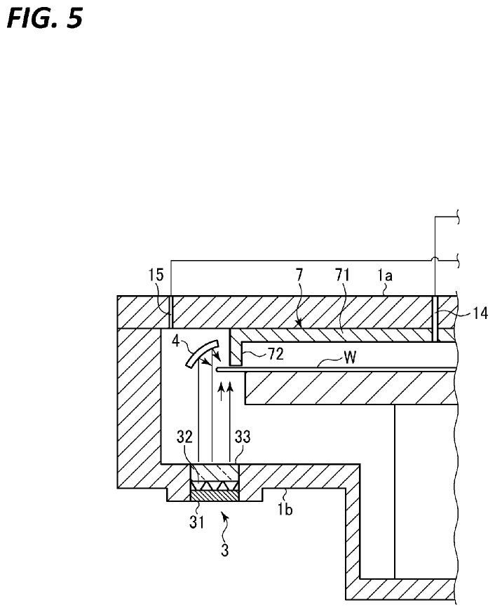

FIG. 5 is a cross-sectional view schematically illustrating an example of a substrate processing apparatus according to another embodiment. In the present embodiment, the LED heating unit 3, which has a ring-like overall shape with a diameter larger than the substrate stage 2, is provided at a position below the substrate W on the substrate stage 2, for example, on a bottom wall 1b of the processing container 1, and the mirror 4 which is a reflective member is disposed above the substrate W. In the present embodiment as well, the peripheral edge of the substrate W may be irradiated with LEDs, so that carbon-containing substances present at the peripheral edge may be heated.

Next, still another embodiment will be described.

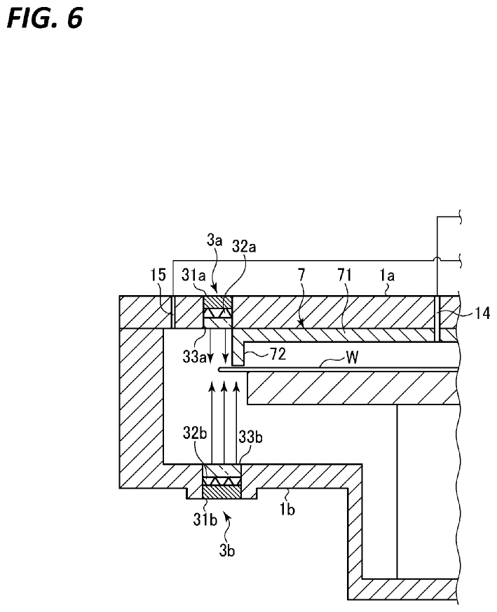

FIG. 6 is a cross-sectional view schematically illustrating an example of a substrate processing apparatus according to still another embodiment. In the present embodiment, an LED heating unit 3a is provided in the ceiling wall 1a, and an LED heating unit 3b is provided in the bottom wall 1b. The LED heating unit 3a includes a base member 31a, a plurality of LED elements 32a, and a light transmitting member 33a. The LED heating unit 3b includes a base member 31b, a plurality of LED elements 32b, and a light transmitting member 33b. In this configuration, since the LED heating units 3a and 3b are disposed above and below the peripheral edge of the substrate W, the peripheral edge of the substrate W may be irradiated with LED light from both the top and bottom, so that carbon-containing substances present at the peripheral edge of the substrate W may be heated. In the case of the present embodiment, the mirror 4 which is a reflective member is not necessary.

Even when the LED heating unit 3 is provided on either the ceiling wall 1a or the bottom wall 1b of the processing container 1, the mirror 4 is not essential depending on the location of carbon-containing substances to be removed.

In the above embodiments, descriptions have been made on an example in which an LED heating unit is provided in the ceiling wall or/and the bottom wall, but the present disclosure is not limited to this location as long as a required portion of the peripheral edge of the substrate may be irradiated with LED light.

In the above embodiments, descriptions have been made on an example in which a cylindrical member having a space S corresponding to the central portion of the substrate W is used as the shielding member 7, but the present disclosure is not limited to this as long as it is possible to obstruct the flow of an oxygen-containing gas into the central portion of the substrate. For example, the shielding member may have a cylindrical shape that allows a constant gap to be maintained between the shielding member and the substrate. Further, the shielding member may not be provided as long as the removal reaction of carbon-containing substances may occur only at the peripheral edge of the substrate due to, for example, the temperature control of the substrate stage and the supply of an inert gas.

Further, in the above embodiments, regarding a substrate on which a carbon-containing film for forming an air gap in a device, such as a polyurea film, is formed, a case where the carbon-containing film at the peripheral edge of the substrate is removed have been described. Meanwhile, it is possible to employ other cases, such as a case in which etching by-products formed on the peripheral edge of the substrate, e.g., a polymer, are removed.

Furthermore, in the above embodiments, a semiconductor wafer is exemplified as a substrate, but the present disclosure is not limited to this. Other substrates such as a flat panel display (FPD) substrate or a ceramic substrate may be employed.

According to the present disclosure, a substrate processing apparatus and a substrate processing method are provided, which are capable of efficiently removing carbon-containing substances present at the peripheral edge of the substrate, with good controllability, while suppressing damage to the substrate.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A substrate processing apparatus comprising:
a processing container;
a substrate stage configured to place the substrate thereon within the processing container and support at least a portion of the substrate excluding a peripheral edge;
an LED heater including a plurality of LED elements and configured to irradiate the peripheral edge of the substrate with LED light from the plurality of LED elements, thereby heating a carbon-containing substance present at the peripheral edge; and
a gas supply configured to supply an oxygen-containing gas to the peripheral edge of the substrate.

2. The substrate processing apparatus according to claim 1, wherein the LED heater has a ring-like overall shape with a diameter larger than the substrate stage.

3. The substrate processing apparatus according to claim 2, wherein the LED heater includes a ring-shaped base, and the plurality of LED elements are provided in the base.

4. The substrate processing apparatus according to claim 2, wherein the LED heater is provided at a position above or a position below the substrate on the substrate stage, or at both positions.

5. The substrate processing apparatus according to claim 2, further comprising a reflector configured to reflect LED light emitted from the plurality of LED elements of the LED heater and guide the reflected light to the peripheral edge of the substrate.

6. The substrate processing apparatus according to claim 5, wherein the LED heater is provided above the substrate on the substrate stage, and the reflector is provided below the substrate on the substrate stage.

7. The substrate processing apparatus according to claim 6, wherein the LED heater is configured such that an inner diameter of the LED heater is smaller than an outer diameter of the substrate on the substrate stage, and an outer diameter of the LED heater is larger than the outer diameter of the substrate on the substrate stage, and
the LED light from the LED elements provided on an inner side of the LED heater is directly irradiated on an upper surface portion of the peripheral edge of the substrate, and the reflected light, which has been emitted from the LED elements provided on an outer side of the LED heater and reflected by the reflector, is irradiated on a lower surface portion of the peripheral edge of the substrate.

8. The substrate processing apparatus according to claim 1, further comprising:
a shield configured to shield a flow of the oxygen-containing gas from the peripheral edge of the substrate to a central portion of the substrate.

9. The substrate processing apparatus according to claim 8, wherein an outer periphery of the shield extends from a ceiling wall of the processing container to a position close to the substrate on the substrate stage, and
the gas supply supplies an inert gas such that the inert gas flows outwards from a gap between the outer periphery and the substrate.

10. The substrate processing apparatus according to claim 9, wherein the shield has a cylindrical shape that has an outer circumferential wall forming the outer periphery, and a space formed inside the outer circumferential wall, and the gap is formed between a lower end of the outer circumferential wall and the substrate on the substrate stage, and
the gas supply supplies the inert gas to the space such that the inert gas flows outwards from the gap.

11. The substrate processing apparatus according to claim 9, wherein a size of the gap is 1 mm or less.

12. The substrate processing apparatus according to claim 8, wherein an outer diameter of the shield is larger than an outer diameter of the substrate stage.

13. The substrate processing apparatus according to claim 8, wherein an outer circumferential surface of the shield is mirror-finished.

14. The substrate processing apparatus according to claim 1, wherein a wavelength of the LED light emitted from the LED elements ranges from 1.5 μm to 3 μm.

15. The substrate processing apparatus according to claim 1, wherein an inner surface of the processing container is mirror-finished.

16. The substrate processing apparatus according to claim 1, wherein a temperature of the carbon-containing substance heated by the LED light is 300° C. or less.

17. A substrate processing method comprising:
placing a substrate on a substrate stage that supports at least a portion of the substrate excluding a peripheral edge;
irradiating the peripheral edge of the substrate with LED light from a plurality of LED elements of a LED heater, thereby heating a carbon-containing substance present at the peripheral edge; and
supplying an oxygen-containing gas to the peripheral edge of the substrate, so that a reaction is caused between the carbon-containing substance heated in the irradiating and the oxygen-containing gas, thereby removing the carbon-containing substance.
